(19) United States
(12) Patent Application Publication
(10) Pub. No.: US 2025/0294796 A1
(43) Pub. Date: Sep. 18, 2025

(54) GATE ALL AROUND FIELD EFFECT TRANSISTOR HAVING MULTIPLE GATE STACK STRUCTURE AND FABRICATION METHOD THEREFOR

(71) Applicants: ELECTRONICS AND TELECOMMUNICATIONS RESEARCH INSTITUTE, Daejeon (KR); Korea Advanced Institute Of Science And Technology, Daejeon (KR); KOREA INSTITUTE OF SCIENCE AND TECHNOLOGY, Seoul (KR)

(72) Inventors: Sung Haeng CHO, Daejeon (KR); Seong Keun KIM, Seoul (KR); Byung Jin CHO, Daejeon (KR)

(73) Assignees: ELECTRONICS AND TELECOMMUNICATIONS RESEARCH INSTITUTE, Daejeon (KR); Korea Advanced Institute Of Science And Technology, Daejeon (KR); KOREA INSTITUTE OF SCIENCE AND TECHNOLOGY, Seoul (KR)

(21) Appl. No.: 19/078,695

(22) Filed: Mar. 13, 2025

(30) Foreign Application Priority Data
Mar. 13, 2024 (KR) 10-2024-0035452
Mar. 10, 2025 (KR) 10-2025-0030483

(51) Int. Cl. H10D 30/00; H10D 30/01; H10D 30/43; H10D 62/10; H10D 62/80

(52) U.S. Cl. CPC H10D 30/504; H10D 30/014; H10D 30/0191; H10D 30/43; H10D 62/121; H10D 62/875

(57) ABSTRACT

A semiconductor device fabrication method may comprise: alternately and sequentially stacking a source/drain electrode layer forming a source/drain and a channel layer forming an oxide semiconductor channel; stacking a mask layer to surround a portion where a source/drain region is to be formed; exposing a channel layer of a channel region by etching and removing the source/drain electrode layer of the channel region exposed through the mask layer; and sequentially forming a gate dielectric layer and at least one gate electrode layer on the exposed channel layer of the channel region and on exposed lateral sides of the source/drain electrode layer of the source/drain region.

### CROSS-REFERENCE TO RELATED APPLICATIONS

This application claims priority to Korean Patent Applications No. 10-2024-0035452, filed on Mar. 13, 2024, and No. 10-2025-0030483, filed on Mar. 10, 2025, with the Korean Intellectual Property Office (KIPO), the entire contents of which are hereby incorporated by reference.

### BACKGROUND

### 1. Technical Field

The disclosure belongs to a technical field of fabricating a semiconductor device, and specifically relates to a transistor for implementing semiconductor logic circuits and devices and a fabrication method thereof.

### 2. Related Art

The statements in this section merely provide background information related to the present embodiments and may not constitute the prior art.

Technology for metal oxide semiconductor field-effect transistor (MOSFET) device and process has simultaneously achieved two goals of improving the performance of a semiconductor and increasing a degree of integration of the transistor with continuous development of scale down technology.

This achievement brought innovations in a transistor structure through the improvement in field-effect mobility based on the stress engineering for an Si semiconductor, the introduction of high dielectric gate insulator and metal electrode gate (High K/Metal Gate) technology, and the introduction of fin-type FETs (Fin-FETs) capable of suppressing the negative effects of short channels by improved gate field control capability effective in devices having a channel length of 28 nm.

For a transistor having a channel length of less than 5 nm, a Gate-All-Around FET structure more advanced than the Fin-FET is being attempted. Unlike the Fin-FET that supplies a gate field to three sides of the channel, the Gate-All-Around FET applies the gate field to all sides of the channel and thus maximizes the gate field control capability, in particular, for a short channel structure. Accordingly, the Gate-All-Around FET is expected to have advantages of suppressing the negative effects of a short channel and maximizing the performance.

### SUMMARY

An aspect of the disclosure is to propose a transistor structure for semiconductor logic circuits and devices, which require high-speed operations while having computational functions such as logic circuits, and a fabrication method thereof.

Another aspect of the disclosure is to propose a structure of a semiconductor device, which implements a nanosheet oxide semiconductor Gate All Around (GAA) field effect transistor that includes a semiconductor material other than Si or SiGe, in particular, an oxide semiconductor as a channel material when implementing a field effect transistor of a nanosheet type GAA structure, and a fabrication process technology therefor.

According to an exemplary embodiment of the present disclosure, a semiconductor device fabrication method may comprise: alternately and sequentially stacking a source/drain electrode layer forming a source/drain and a channel layer forming an oxide semiconductor channel; stacking a mask layer to surround a portion where a source/drain region (or source/drain electrode) is to be formed; exposing a channel layer of a channel region by etching and removing the source/drain electrode layer of the channel region exposed through the mask layer; and sequentially forming a gate dielectric layer and at least one gate electrode layer on the exposed channel layer of the channel region and on exposed lateral sides of the source/drain electrode layer of the source/drain region.

The sequentially forming the gate dielectric layer and the at least one gate electrode layer may comprise: forming the gate dielectric layer and the at least one gate electrode layer so that the gate dielectric layer is arranged for insulation between the channel layers and the gate dielectric layer is arranged for insulation between the channel layer and the at least one gate electrode layer, and the gate dielectric layer is arranged for insulation between the at least one gate electrode layer and the exposed lateral sides of the source/drain electrode layer of the source/drain region.

The sequentially forming the gate dielectric layer and the at least one gate electrode layer may comprise: depositing the gate dielectric layer to surround the exposed channel layer in the channel region and the exposed lateral sides of the source/drain electrode layer of the source/drain region while maintaining the mask layer surrounding the portion where the source/drain region (or source/drain electrode) is to be formed.

The sequentially forming the gate dielectric layer and the at least one gate electrode layer may comprise: depositing a first gate dielectric layer to surround the exposed gate dielectric layer in the channel region while maintaining the mask layer surrounding the portion where the source/drain region (or source/drain electrode) is to be formed.

The sequentially forming the gate dielectric layer and the at least one gate electrode layer may comprise: depositing a second gate electrode layer to surround the first gate electrode layer in the channel region.

The semiconductor device fabrication method may further comprise: performing a dry etching process for the at least one gate electrode layer until the mask layer is exposed; and removing the mask layer.

The channel layer may comprise an N-type channel layer, and the channel layer may be formed of an oxide semiconductor compound that contains two or more elements from a group consisting of In, Ga, Zn, Sn, and O and has a band gap energy of 1.5 eV or more.

The channel layer may be formed of an oxide semiconductor compound that contains at least one element among Al, W, Hf and/or Ta as impurities.

The channel layer may comprise a P-type channel layer, and the channel layer may be formed of an oxide semiconductor compound that contains one or more elements from a group consisting of Zn, Te, Se, N, and O and has a band gap energy of 1.5 eV or more.

The gate dielectric layer may comprise a dielectric film that contains at least one of Al₂O₃, SiO₂, HfOₓ, and/or ZrOₓ.

According to an exemplary embodiment of the present disclosure, a semiconductor device may comprise: a plurality of oxide semiconductor channel layers formed to extend in a first direction in a source/drain region and a channel region and formed in plural in a second direction intersecting the first direction; a plurality of source/drain electrode layers formed between the plurality of oxide semiconductor channel layers in the second direction in the source/drain region; a gate dielectric layer disposed between the plurality of source/drain electrode layers in the first direction in the channel region and disposed between the plurality of oxide semiconductor channel layers of the channel region in the second direction; and at least one gate electrode layer formed to be connected between the gate dielectric layers in the channel region and formed to be connected to gate power.

The plurality of oxide semiconductor channel layers and the plurality of source/drain electrode layers are alternately stacked in the second direction in the source/drain region.

The gate dielectric layer may be formed for insulation between the plurality of oxide semiconductor channel layers, and formed for insulation between the plurality of oxide semiconductor channel layers and the at least one gate electrode layer, and formed for insulation between the at least one gate electrode layer and the exposed lateral sides of the source/drain electrode layer of the source/drain region.

The plurality of oxide semiconductor channel layers may comprise an N-type channel layer, and the plurality of oxide semiconductor channel layers may be formed of an oxide semiconductor compound that contains two or more elements from a group consisting of In, Ga, Zn, Sn, and O and has a band gap energy of 1.5 eV or more.

The plurality of oxide semiconductor channel layers may be formed of an oxide semiconductor compound that contains at least one element among Al, W, Hf and/or Ta as impurities.

The plurality of oxide semiconductor channel layers may comprise a P-type channel layer, and the plurality of oxide semiconductor channel layers may be formed of an oxide semiconductor compound that contains one or more elements from a group consisting of Zn, Te, Se, N, and O and has a band gap energy of 1.5 eV or more.

The gate dielectric layer may comprise a dielectric film that contains at least one of Al₂O₃, SiO₂, HfOₓ, and/or ZrOₓ.

The semiconductor device may further comprise: a first semiconductor device of a first polarity type formed comprising the plurality of oxide semiconductor channel layers, the plurality of source/drain electrode layers, the gate dielectric layer, and the at least one gate electrode layer; and a second semiconductor device of a second polarity type formed comprising a plurality of second oxide semiconductor channel layers, a plurality of second source/drain electrode layers, a second gate dielectric layer, and at least one second gate electrode layer.

The first polarity type and the second polarity type may be complementary to each other, the first semiconductor device and the second semiconductor device may be sequentially stacked in the second direction, and the first semiconductor device and the second semiconductor device may be configured to perform complementary logic operations.

According to an exemplary embodiment of the present disclosure, a semiconductor device may comprise: a plurality of oxide semiconductor channel layers formed to extend in a first direction in a source/drain region and a channel region and formed in plural in a second direction intersecting the first direction; and a plurality of source/drain electrode layers formed between the plurality of oxide semiconductor channel layers in the second direction in the source/drain region.

The plurality of oxide semiconductor channel layers and the plurality of source/drain electrode layers may be alternately stacked in the second direction in the source/drain region.

A space may be formed between the plurality of oxide semiconductor channel layers in the second direction in the channel region to expose the plurality of oxide semiconductor channel layers.

According to an embodiments of the disclosure, the oxide semiconductor channel layer and the S/D electrode layer of the nanosheet structure are multiple-stacked, thereby increasing the effective channel width.

According to an embodiment of the disclosure, the gate electrode and the S/D electrode are insulated from each other, thereby reducing the vertical overlap parasitic capacitance between the gate electrode and the S/D electrode.

According to an embodiment of the disclosure, a device fabrication technology applicable to the class of the semiconductor device/process of 10 nm or less without using the Si material may be provided.

According to an embodiment of the disclosure, the semiconductor device may be implemented directly on a wafer of a general Si CMOS device without using a packaging process such as a through silicon via (TSV) or an Si interposer.

### BRIEF DESCRIPTION OF DRAWINGS

FIG. 1 is a conceptual view of a semiconductor device 110 that has undergone some steps of a semiconductor fabrication process according to an embodiment of the disclosure.

FIG. 2 is a conceptual view of a semiconductor device 120 formed by applying some additional steps to the semiconductor device 110 of FIG. 1.

FIG. 3 is a conceptual view of a semiconductor device 130 formed by applying some additional steps to the semiconductor device 120 of FIG. 2.

FIG. 4 is a cross-sectional view illustrating the semiconductor device 130 of FIG. 3.

FIG. 5 is a conceptual cross-sectional view showing a semiconductor device 140 formed by applying some additional steps to the semiconductor device 130 of FIGS. 3 and 4.

FIG. 6 is a conceptual cross-sectional view showing a semiconductor device 150 formed by applying some additional steps to the semiconductor device 140 of FIG. 5.

FIG. 7 is a conceptual cross-sectional view of a semiconductor device 160 formed by applying some additional steps to the semiconductor device 150 of FIG. 6.

FIG. 8 is a cross-sectional view illustrating the semiconductor device 160 of FIG. 7.

FIG. 9 is a flow chart showing a fabrication method of a semiconductor device according to an embodiment of the disclosure.

FIG. 10 is a conceptual view of the structure for a semiconductor device according to an embodiment of the disclosure.

FIG. 11 is a conceptual view illustrating a structure of a semiconductor device according to another embodiment of the disclosure.

### DETAILED DESCRIPTION OF THE EMBODIMENTS

While the present disclosure is capable of various modifications and alternative forms, specific embodiments thereof are shown by way of example in the drawings and will herein be described in detail. It should be understood, however, that there is no intent to limit the present disclosure to the particular forms disclosed, but on the contrary, the present disclosure is to cover all modifications, equivalents, and alternatives falling within the spirit and scope of the present disclosure. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

In exemplary embodiments of the present disclosure, “at least one of A and B” may refer to “at least one A or B” or “at least one of one or more combinations of A and B”. In addition, “one or more of A and B” may refer to “one or more of A or B” or “one or more of one or more combinations of A and B”.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (i.e., “between” versus “directly between,” “adjacent” versus “directly adjacent,” etc.).

The terminology used herein is for the purpose of describing particular embodiments only and is not intended to be limiting of the present disclosure. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this present disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Meanwhile, even if a technology is known prior to the filing date of the present disclosure, it may be included as part of the configuration of the present disclosure when necessary, and will be described herein without obscuring the spirit of the present disclosure. However, in describing the configuration of the present disclosure, a detailed description on matters that can be clearly understood by those skilled in the art as a known technology prior to the filing date of the present disclosure may obscure the purpose of the present disclosure, so excessively detailed description on the known technology will be omitted.

However, the purpose of the disclosure is not to claim the rights to these known technologies, and the contents of the known technologies may be included as part of the disclosure without departing from the scope of the disclosure.

Hereinafter, exemplary embodiments of the disclosure will be described in more detail with reference to the accompanying drawings. To facilitate an overall understanding in the description of the disclosure, the same reference numerals will be assigned to the same components throughout the accompanying drawings, and redundant descriptions thereof will be omitted.

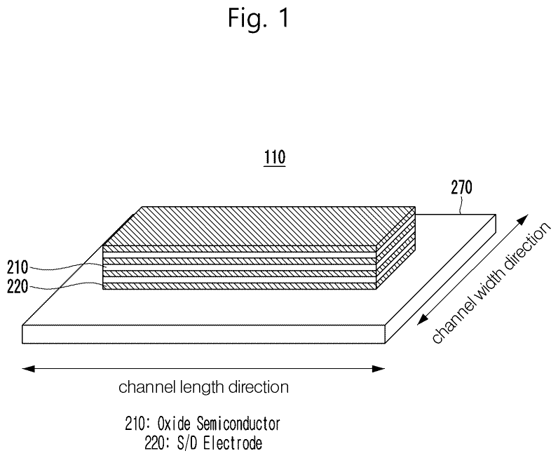

FIG. 1 is a conceptual view of a semiconductor device 110 that has undergone some steps of a semiconductor fabrication process according to an embodiment of the disclosure.

Referring to FIG. 1, a metal thin film for source and drain electrodes (hereinafter referred to as “S/D electrode 220”) may be formed on a predetermined substrate 270, and a thin film of an oxide semiconductor channel layer 210 may be formed on the thin film of the S/D electrode 220.

The thin film of the S/D electrode 220 and the thin film of the channel layer 210 are alternately stacked in a vertical direction, and the thin film of the S/D electrode 220 may be formed on the top.

Lithography may be used to form a pattern having a predetermined length in a channel length direction and a predetermined width in a channel width direction. In this case, the pattern may be formed as a ribbon-shaped pattern in which a source/drain region has a wider width than a channel region, but the spirit of the disclosure is not construed as being limited to this pattern.

In this case, a metal thin film of Mo, TiN, TiW, Mo, Cu, etc. having low resistance characteristics may be used as the S/D electrode 220, and may selectively use metal having a high etching selectivity with respect to the channel layer 210.

In an alternative embodiment of the disclosure, an additional process of etching S/D electrode layer 220 and oxide semiconductor channel layer 210 (which are alternately and sequentially stacked) together to form a shape having isolated islands as shown in FIG. 1 may be performed.

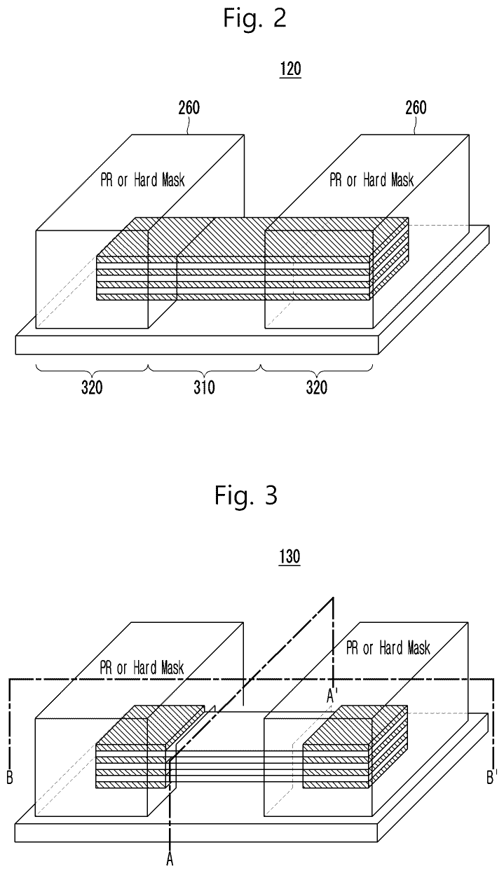

FIG. 2 is a conceptual view of a semiconductor device 120 formed by applying some additional steps to the semiconductor device 110 of FIG. 1.

Referring to FIG. 2, the semiconductor device 120 has a pattern of a multi-layered stack structure in which the S/D electrodes 220 and semiconductor material channel layers 210 are continuously and alternately deposited in a nanosheet form.

A lithography process may be applied to the semiconductor device 110 of FIG. 1 to expose only a portion corresponding to a channel length. In this case, the exposed region may be a region to form a channel region 310 later. Further, as shown in FIG. 2, a region covered with a mask layer 260 including a photoresist PR or a hard mask may be a region to form S/D region 320 later.

In this case, the mask used as the mask layer 260 may use an organic photosensitive film of which solubility varies depending on light, or an inorganic insulating film of SiOx, SiNx, AlOx, HfOx, etc.

FIG. 3 is a conceptual view of a semiconductor device 130 formed by applying some additional steps to the semiconductor device 120 of FIG. 2.

Referring to FIG. 3, the exposed S/D electrode of each layer in the semiconductor device 120 shown in FIG. 2 may be removed using an S/D electrode etchant having a high etching selectivity with respect to the oxide semiconductor.

In this case, the S/D etchant employs an etchant having a high etching selectivity with respect to the channel layer 210, which may be a solution or gas etchant. In other words, the S/D etchant may etch and remove only the exposed portion of the S/D electrode 220 while leaving the channel layer 210.

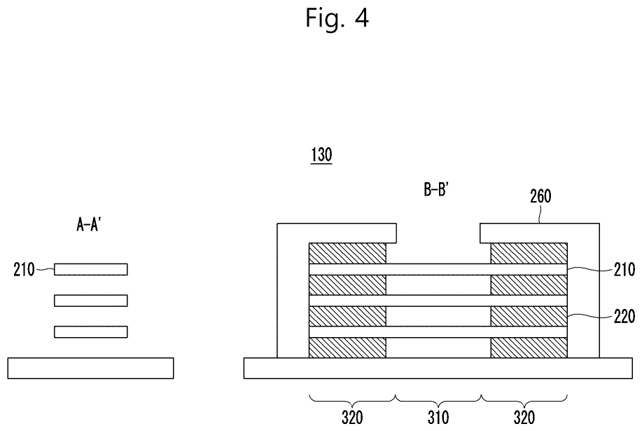

FIG. 4 is a cross-sectional view illustrating the semiconductor device 130 of FIG. 3.

Referring to FIG. 4, a cross-section taken along line A-A′ and a cross-section taken along line B-B′ of the channel are shown after the exposed portion of the S/D electrode 220 is removed.

In the channel region 310, only the channel layer 210 remains. In the S/D region 320, thin film layers of the channel layer 210 and the S/D electrode 220 are alternately stacked.

In the channel region 310, the upper surfaces and the lower surfaces of the channel layer 210 may be exposed, in the S/D region 320, the side surfaces of the thin-film layers of the S/D electrode 220 may be exposed, as shown in FIGS. 3 and 4.

In this case, the thin film layer of the S/D electrode 220 may be undercut to the inside of the mask layer 260 by the S/D etchant, but the thin film layer of the S/D electrode 220 remaining in the S/D region 320 may be maintained by controlling process conditions.

Referring to FIGS. 3 and 4, the semiconductor device 130 according to an embodiment of the disclosure may include a plurality of oxide semiconductor channel layers 210 formed to extend in a first direction in a source/drain region 320 and a channel region 310 and formed in a second direction intersecting the first direction; and a plurality of source/drain electrode layers 220 formed between the plurality of oxide semiconductor channel layers 210 in the source/drain region 320 in the second direction.

The first direction may be a channel length direction.

The second direction may be a vertical direction.

Meanwhile, each of the channel layer 210 and the S/D electrode layer 220 may also have a predetermined width in a channel width direction.

In the semiconductor device 130 according to an embodiment of the disclosure, a plurality of oxide semiconductor channel layers 210 and a plurality of source/drain electrode layers 220 may be alternately stacked in the source/drain region 320 in the second direction.

In the semiconductor device 130 according to an embodiment of the disclosure, an empty space may be formed between the plurality of oxide semiconductor channel layers 210 in the channel region 310 in the second direction to expose the plurality of oxide semiconductor channel layers 210.

In the semiconductor device 130 according to an embodiment of the disclosure, the S/D electrode layer 220 in the channel region 310 may be removed as a sacrificial layer.

In the semiconductor device 130 according to an embodiment of the disclosure, the S/D electrode layer 220 is not removed in the S/D region 320, and thus the S/D electrode layer 220 remains between the oxide semiconductor channel layers 210 stacked in the vertical direction. In other words, the oxide semiconductor channel layers 210 stacked in the vertical direction may be divided from each other by the S/D electrode layer 220 remaining in the S/D region 320.

In the semiconductor device 130 according to an embodiment of the disclosure, the length in the channel length direction of the exposed channel layer 210 may correspond to the channel length of the completed semiconductor device 160 to be described later, and the width in the channel width direction of the exposed channel layer 210 may correspond to the channel width of the completed semiconductor device 160.

The S/D electrode layer 220 remaining in the S/D region 320 may be structured to extend horizontally on the upper and lower surfaces of the channel layer 210 in each of the S/D regions 320 in order to function as a source or drain electrode in the future.

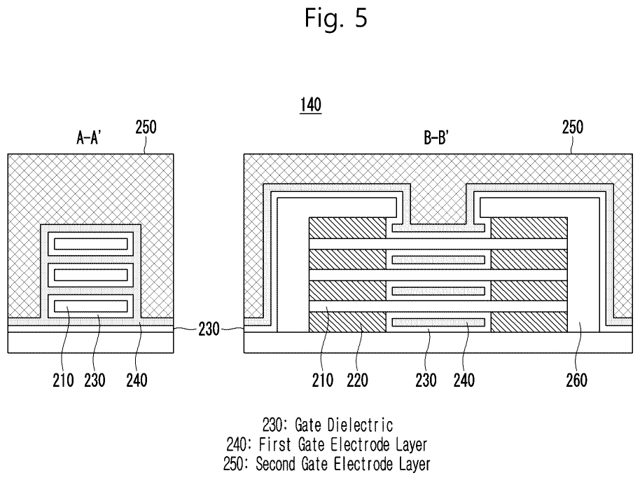

FIG. 5 is a conceptual cross-sectional view showing a semiconductor device 140 formed by applying some additional steps to the semiconductor device 130 of FIGS. 3 and 4.

In the state that the mask layer 260 is not removed from the semiconductor device 130 of FIG. 3 and FIG. 4, a gate dielectric 230 and a first gate electrode 240 are sequentially deposited using a processing technique for excellent surface coverage, such as atomic layer deposition (ALD), and then a second gate electrode 250 having lower resistance than the first gate electrode 240 is deposited using a device for processing, such as sputtering, thereby forming a semiconductor device 140 of FIG. 5.

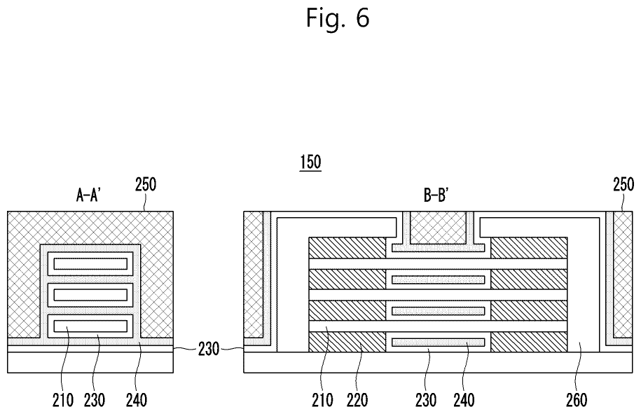

FIG. 6 is a conceptual cross-sectional view showing a semiconductor device 150 formed by applying some additional steps to the semiconductor device 140 of FIG. 5.

The semiconductor device 150 of FIG. 6 may be formed after applying dry etching to the entire area of the semiconductor device 140 of FIG. 5 until the mask layer 260 covered with the layer of the second gate electrode 250 layer is exposed.

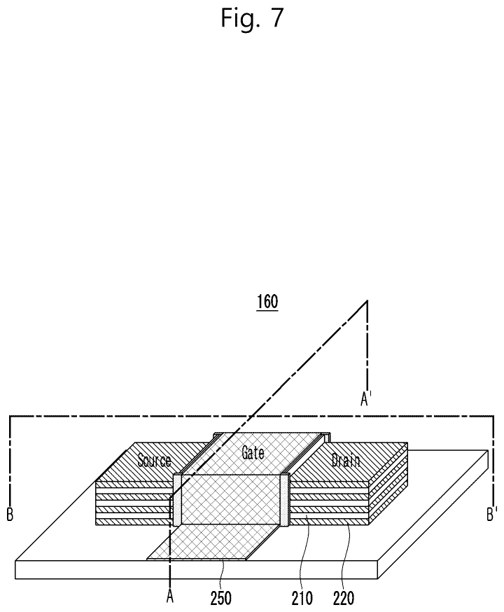

FIG. 7 is a conceptual view of a semiconductor device 160 formed by applying some additional steps to the semiconductor device 150 of FIG. 6.

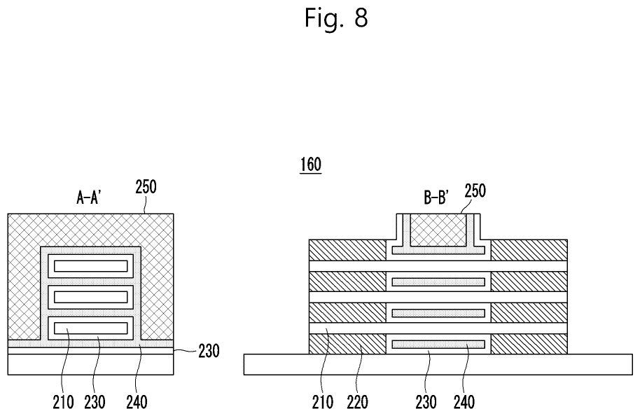

According to an embodiment of the disclosure, FIGS. 7 and 8 may be understood as conceptually illustrating the semiconductor device 160 for which semiconductor full processing has been completed.

In an alternative embodiment of the disclosure, a semiconductor circuit or a semiconductor device may be implemented by an additional process using the semiconductor device 160.

Referring to FIG. 7, when the mask layer 260 is removed from the semiconductor device 150 of FIG. 6 and the patterning for the gate electrodes 240 and 250 is performed through general lithography, a transistor in a form completed by the full process may be implemented as the semiconductor device 160.

FIG. 8 is a cross-sectional view illustrating the semiconductor device 160 of FIG. 7.

Referring to FIGS. 7 and 8, the semiconductor device 160 according to an embodiment of the discontinuation may include the plurality of oxide semiconductor channel layers 210 formed in the source/drain region 320 and the channel region 310 to extend in the first direction and formed in plural in the second direction intersecting the first direction; a plurality of source/drain electrode layers 220 formed between the plurality of oxide semiconductor channel layers 210 in the second direction in the source/drain region 320; the gate dielectric layer 230 disposed between the plurality of source/drain electrode layers 220 in the first direction in the channel region 310 and disposed between the plurality of oxide semiconductor channel layers 210 of the channel region 310 in the second direction; and at least one gate electrode layer 240, 250 formed to be connected between the gate dielectric layers 230 in the channel region 310 and formed to be connected to gate power.

The first direction may be the channel length direction. The semiconductor device 160 may have a structure in which the S/D region 320 may extend on both sides of the channel region 310 along the first direction.

The second direction may be the vertical direction.

Meanwhile, each of the channel layer 210 and the S/D electrode layer 220 may have a predetermined width in the channel width direction.

In the semiconductor device 160 according to an embodiment of the disclosure, the plurality of oxide semiconductor channel layers 210 and the plurality of source/drain electrode layers 220 may be alternately stacked in the second direction in the source/drain region 320. The plurality of oxide semiconductor channel layers 210 and the plurality of source/drain electrode layers 220 may be structured to extend in the horizontal direction as a nanosheet structure.

In the channel region 310, the source/drain electrode layer 220 is removed as the sacrificial layer, and thus the channel layers 210 may be spaced apart from each other in the vertical direction.

In the S/D region 320, the source/drain electrode layer 220 is not removed, and thus the source/drain electrode layers 220 may be spaced apart in the vertical direction by the channel layers 210, and the channel layers 210 may be spaced apart in the vertical direction by the source/drain electrode layers 220.

In the semiconductor device 160 according to an embodiment of the disclosure, each of the gate electrodes 240 and 250 and the S/D electrode 220 after the patterning is formed by an etching process accompanied by a single mask layer 260, thereby having a self-aligned structure without upper and lower overlap.

In the semiconductor device 160 according to an embodiment of the disclosure, the gate dielectric layer 230 may be formed between the plurality of oxide semiconductor channel layers 210 in the vertical direction for insulation between the plurality of oxide semiconductor channel layers 210 in the channel region 310, and may be formed for insulation between the plurality of oxide semiconductor channel layers 210 and the first gate electrode layer 240 of the at least one gate electrode layer.

In the semiconductor device 160 according to an embodiment of the disclosure, the gate dielectric layer 230 may be formed between the plurality of oxide semiconductor channel layers 210 and the side surfaces of the S/D electrode 220 of the S/D region 320 for insulation between the plurality of oxide semiconductor channel layers 210 and the side surfaces of the S/D electrode 220 of the S/D region 320.

In the semiconductor device 160 according to an embodiment of the disclosure, the side wall of the S/D electrode 220 and the side wall of the gate electrodes 240 and 250 may be insulated by the gate dielectric layer 230. Alternatively, the side wall of the S/D electrode 220 and the side wall of the gate electrodes 240 and 250 may be insulated by the gate dielectric layer 230, an air gap, or a mixture with another insulating film. In the semiconductor device 160 according to an embodiment of the disclosure, lateral parasitic capacitance between the gate and the S/D may be reduced by insulating the side wall of the S/D electrode 220 and the side wall of the gate electrodes 240 and 250.

In the semiconductor device 160 according to an embodiment of the disclosure, the gate electrodes between the channel layers 210 may be directly connected without using a via hole, and so on as the first gate electrode layers 240 are connected to each other in the process of deposition of the gate electrodes.

The first gate electrode layer 240, which surrounds the channel layer 210 and the gate dielectric layer 230, and the second gate electrode layer 250, which is formed on the uppermost layer forming a nanosheet channel, may be formed of the same material or may be formed of different materials. In this case, the second gate electrode layer 250 may be formed as an electrode having lower resistance than the first gate electrode layer 240.

In the semiconductor device 160 according to an embodiment of the disclosure, the length of an effective channel may be longer than the length of the gate electrodes 240 and 250 formed in FIGS. 7 and 8 in the channel length direction.

In the semiconductor device 160 according to an embodiment of the disclosure, a region where the channel layer 210 surrounded by the gate dielectric layer 230 is located may be defined as the channel region 310 for convenience of description.

The region being in contact with the S/D electrode layer 220, where the channel layer 210 remains, may be defined as the S/D region 320, and the channel layer 210 belonging to the S/D region 320 may also be referred to as an S/D extension region for convenience of description.

According to an embodiment of the disclosure, the channel layer 210 of the S/D extension region and the channel layer 210 of the channel region 310 may be formed of the same material. In an alternative embodiment of the disclosure, the channel layer 210 of the S/D extension region and the channel layer 210 of the channel region 310 may have the same polarity type (N/P) but differ only in carrier concentration.

As described below, when the composition of the channel layer 210 is selected to be a material having a larger bandgap than the Si material, an ohmic contact may be formed between the channel layer 210 and the S/D electrode layer 220 in the S/D extension region without the need for an additional process.

According to an embodiment of the disclosure, a GAA process without processes for a dummy gate, a spacer, etc. is very simplified compared to the conventional GAA process.

In the semiconductor device according to an embodiment of the disclosure, the plurality of oxide semiconductor channel layers may be an N-type channel layer, and the plurality of oxide semiconductor channel layers may be formed of an oxide semiconductor compound that contains two or more elements from the group consisting of In, Ga, Zn, Sn, and O and has a band gap energy of 1.5 eV or more.

In the semiconductor device according to an embodiment of the disclosure, the plurality of oxide semiconductor channel layers may be formed of an oxide semiconductor compound including at least one element of Al, W, Hf, and/or Ta as an impurity.

In the semiconductor device according to an embodiment of the disclosure, the plurality of oxide semiconductor channel layers may be a P-type channel layer, and the plurality of oxide semiconductor channel layers may be formed of an oxide semiconductor compound that contains one or more elements from the group consisting of Zn, Te, Se, N, and O and has a band gap energy of 1.5 eV or more.

In the semiconductor device according to an embodiment of the disclosure, the dielectric layer may include a dielectric film including at least one of Al₂O₃, SiO₂, HfOₓ, and/or ZrOₓ.

The channel layer may be an oxide semiconductor that does not use a Si material.

The ohmic contact may be formed directly between the S/D electrode and the oxide semiconductor channel layer. In particular, due to the oxide semiconductor channel layer having a band gap energy of 1.5 eV or more, the ohmic contact may be formed directly between the S/D electrode and the oxide semiconductor channel layer without the need for a separate dopant other than the elements that constitute the S/D electrode and the oxide semiconductor channel layer.

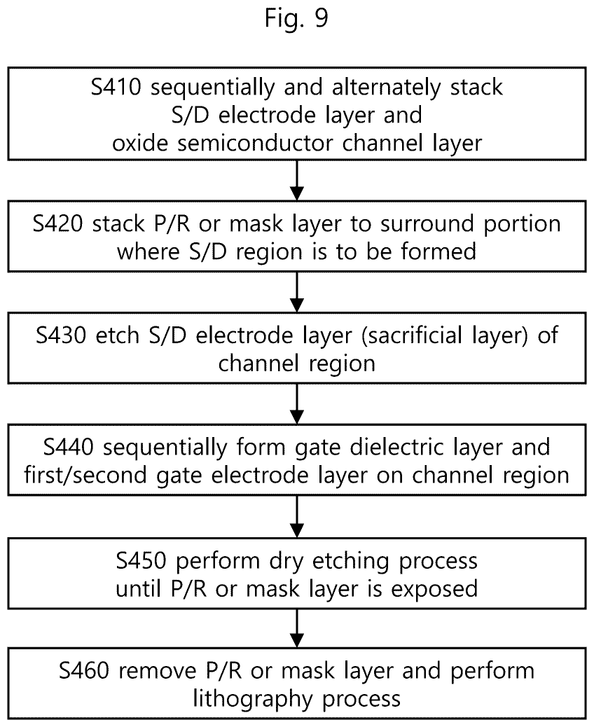

FIG. 9 is a flow chart showing a fabrication method of a semiconductor device according to an embodiment of the disclosure.

The fabrication method according to an embodiment of the disclosure the semiconductor device include steps of sequentially and alternately stacking the source/drain electrode layers 220 forming a source/drain and the channel layer 210 forming an oxide semiconductor channel (S410); stacking the mask layer 260 to surround a portion where the source/drain region is to be formed (S420); exposing the channel layer 210 of the channel region 310 by etching and removing the source/drain electrode layers 220 of the channel region 310 exposed through the mask layer 260 (S430); and sequentially forming the gate dielectric layer 230 and at least one gate electrode layer 240, 250 on the exposed channel layer 210 of the channel region 310 (S440).

In an alternative embodiment of the disclosure, an additional process of etching S/D electrode layer 220 and oxide semiconductor channel layer 210 (which are alternately and sequentially stacked in S410) together to form a shape having isolated islands as shown in FIG. 1 may be added after the process of S410.

Based on the etching process of S430, in the channel region 310, the upper surfaces and the lower surfaces of the channel layer 210 may be exposed, in the S/D region 320, the side surfaces of the thin-film layers of the S/D electrode 220 may be exposed, as shown in FIGS. 3 and 4

In the step S440 of sequentially forming the gate dielectric layer 230 and at least one gate electrode layer 240, 250 on the exposed channel layer 210, the gate dielectric layer 230 and the at least one gate electrode layer 240, 250 may be formed so that 1) the gate dielectric layer 230 can be arranged for insulation between the channel layers 210 in the channel region 310, and 2) the gate dielectric layer 230 can be arranged for insulation between the exposed channel layer 210 and the at least one gate electrode layer 240, 250.

In the step S440 of sequentially forming the gate dielectric layer 230, the gate dielectric layer 230 may be formed further so that 3) the gate dielectric layer 230 can be arranged for insulation between the exposed channel layers 210 and the exposed side surfaces of the S/D electrode layers 220 of the S/D region 320.

The step S440 of sequentially forming the gate dielectric layer 230 and at least one gate electrode layer 240, 250 on the exposed channel layer 210 may include a step of depositing the gate dielectric layer 230 to surround the exposed channel layer 210 in the channel region 310 while maintaining the mask layer 260 surrounding the portion where the source/drain region is/are to be formed.

In the step of depositing the gate dielectric layer 230, the channel layer 210 may be surrounded by the dielectric layer in all regions where the channel layer 210 is exposed so that the channel layer 210 can be insulated from other material layers.

In this case, in the step S440 of depositing the gate dielectric layer 230, the exposed side surfaces of the S/D electrode layers 220 of the S/D region 320 may be surrounded by the dielectric layer so that the S/D electrode layers 220 can be insulated from the gate electrode layers 240, 250 to be deposited thereafter.

In this case, the step of depositing the gate dielectric layer 230 may be performed such that the gate dielectric layer 230 surrounds the mask layer 260 in the S/D region 320.

The step S440 of sequentially forming the gate dielectric layer 230 and at least one gate electrode layer 240, 250 on the exposed channel layer 210 may further include a step of depositing the first gate electrode layer 240 to surround the exposed gate dielectric layer 230 in the channel region 310 while maintaining the mask layer 260 surrounding the portion where the source/drain region is to be formed.

In this case, the step of depositing the first gate electrode layer 240 may be performed so that the first gate electrode layer 240 surrounds the mask layer 260 and the gate dielectric layer 230 in the S/D region 320.

In the step of depositing the first gate electrode layer 240, the first gate electrode layer 240 may be deposited such that the first gate electrode layer 240 partially penetrates into an empty space between the gate dielectric layers 230 in the channel region 310 as shown in FIG. 8. In this case, the penetrated portion of the first gate electrode layer 240 may be formed on the upper and lower sides of the semiconductor channel layer 210 of the individual layer so as to function as a gate electrode for the semiconductor channel layer 210 of the individual layer as illustrated in FIG. 8.

In this case, the first gate electrode layer 240 may be formed to be connected as a whole and to come into contact with the second gate electrode layer 250 as shown in the A-A′ cross-section of the channel region 310. The first gate electrode layer 240 may function as a gate electrode for the channel layer 210 in the channel region 310 based on voltage applied from the second gate electrode layer 250, and may serve to control an electric current flowing between the channel layer 210 and the S/D electrode 220 in the S/D region 320.

The step S440 of sequentially forming the gate dielectric layer 230 and at least one gate electrode layer 240, 250 on the exposed channel layer 210 may further include a step of depositing the second gate electrode layer 250 to surround the first gate electrode layer 240 in the channel region 310.

In this case, the step of depositing the second gate electrode layer 250 may be performed such that the second gate electrode layer 250 surrounds the mask layer 260, the gate dielectric layer 230, and the first gate electrode layer 240 in the S/D region 320.

The fabrication method according to an embodiment of the disclosed semiconductor device may further include steps of performing a dry etching process for at least one gate electrode layer 240 or 250 until the mask layer 260 is exposed (S450); and removing the mask layer 260 (S460).

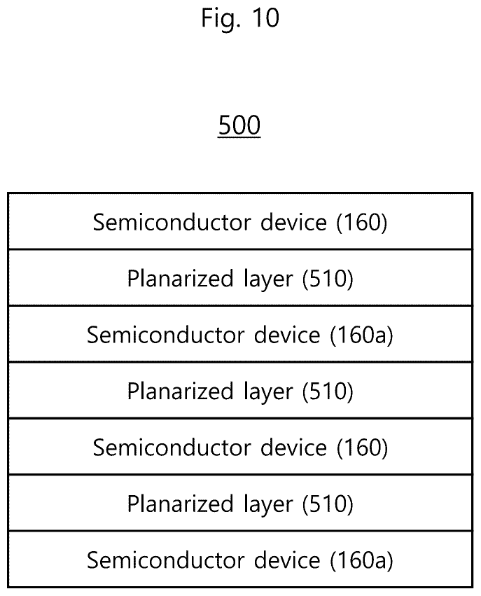

FIG. 10 is a conceptual view of the structure for a semiconductor device according to an embodiment of the disclosure.

Referring to FIG. 10, a semiconductor device 500 according to an embodiment of the disclosure may include a first semiconductor device 160 of a first polarity type formed including the plurality of oxide semiconductor channel layers, the plurality of source/drain electrode layers, the gate dielectric layer, and the at least one gate electrode layer; and a second semiconductor device 160a of a second polarity type formed including a plurality of second oxide semiconductor channel layers, a plurality of second source/drain electrode layers, a second gate dielectric layer, and at least one second gate electrode layer.

In this case, the first polarity type and the second polarity type may be complementary to each other. The first semiconductor device 160 and the second semiconductor device 160a may be sequentially stacked in the second direction.

In this case, when the first semiconductor device 160 is an NMOS and the second semiconductor device 160a is a PMOS, the first semiconductor device 160 and the second semiconductor device 160a may be stacked in the vertical direction to form a complementary FET and configured to perform complementary logic operations.

In this case, each of the first semiconductor device 160 and the second semiconductor device 160a may be a nanosheet GAA-FET, and a planarized layer 510 may be formed between the first semiconductor device 160 and the second semiconductor device 160a to form a vertical structure.

In this case, the planarized layer 510 may be placed between the first semiconductor device 160 and the second semiconductor device 160a, thereby forming a sequentially/repeatedly vertical structure.

The channel layer of the semiconductor device constituting the NMOS and PMOS may be formed of oxide semiconductors different in compositions.

The S/D electrode layer of the semiconductor device constituting the NMOS and PMOS may be formed of electrodes containing different materials, or may be formed of electrodes containing the same material.

The gate electrode layer of the semiconductor device constituting the NMOS and PMOS may be formed of electrodes containing different materials, or may be formed of electrodes containing the same material.

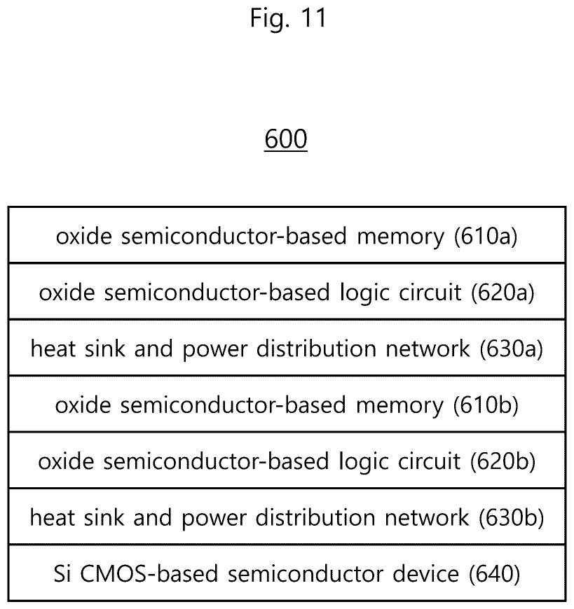

FIG. 11 is a conceptual view illustrating a structure of a semiconductor device according to another embodiment of the disclosure.

Referring to FIG. 11, the semiconductor device 600 may have a structure in which a heat sink and power distribution network layer 630b is placed on a Si CMOS-based semiconductor device 640.

The semiconductor device 600 may have a structure in which an oxide semiconductor-based logic circuit 620b is placed on the heat sink and power distribution network layer 630b.

The semiconductor device 600 may have a structure in which the oxide semiconductor-based memory circuit 620a is placed on the oxide semiconductor-based logic circuit 620b.

The semiconductor device 600 may have a structure in which the oxide semiconductor-based memory circuit 610b—the oxide semiconductor-based logic circuit 620b—the heat sink and power distribution network layer 630b are placed again on the oxide semiconductor-based memory circuit 610a—the oxide semiconductor-based logic circuit 620a—the heat sink and power distribution network layer 630a.

An aspect of the disclosure is to propose a transistor structure for semiconductor logic circuits and devices, which require high-speed operations while having computational functions such as logic circuits, and a fabrication method thereof.

Another aspect of the disclosure is to propose a structure of a semiconductor device, which implements a nanosheet oxide semiconductor Gate All Around (GAA) field effect transistor that includes a semiconductor material other than Si or SiGe, in particular, an oxide semiconductor as a channel material when implementing a field effect transistor of a nanosheet type GAA structure, and a fabrication process technology therefor.

According to the embodiments of the disclosure shown in FIGS. 1 to 11, the oxide semiconductor channel layer and the S/D electrode layer of the nanosheet structure are multiple-stacked, thereby increasing the effective channel width.

According to an embodiment of the disclosure, the gate electrode and the S/D electrode are insulated from each other, thereby reducing the lateral parasitic capacitance between the gate electrode and the S/D electrode.

According to an embodiment of the disclosure, a device fabrication technology applicable to the class of the semiconductor device/process of 10 nm or less without using the Si material may be provided.

According to an embodiment of the disclosure, the semiconductor device may be implemented directly on a wafer of a general Si CMOS device without using a packaging process such as a through silicon via (TSV) or an Si interposer.

According to an embodiment of the disclosure, a semiconductor device capable of implementing a new paradigm of ultra-high integration and low power consumption may be provided.

According to an embodiment of the disclosure, the requirements of semiconductor performance necessary for implementing AI, data-centric computing, etc. which are currently rapidly emerging may be realized.

According to an embodiment of the disclosure, the oxide semiconductor having a large band gap is applied to the GAA process for a node of 5 nm or below, thereby reducing leakage current due to BTBT such as GIDL, which is likely to occur in a short-channel structure. According to an embodiment of the disclosure, the S/D junction process between channels adjacent to the gate may be simplified.

According to an embodiment of the disclosure, a process for fabricating a GAA FET may be simplified by using the S/D electrode as the sacrificial layer.

According to an embodiment of the disclosure, the process can be simplified by using a S/D first—RMG process instead of a general dummy gate first—S/D last-RMG process.

According to an embodiment of the disclosure, a Logic-on-Logic device may be implemented through monolithic three-dimensional stacking by applying a low-temperature process of less than 450 degrees Celsius.

The operations of the method according to the exemplary embodiment of the present disclosure can be implemented as a computer readable program or code in a computer readable recording medium. The computer readable recording medium may include all kinds of recording apparatus for storing data which can be read by a computer system. Furthermore, the computer readable recording medium may store and execute programs or codes which can be distributed in computer systems connected through a network and read through computers in a distributed manner.

The computer readable recording medium may include a hardware apparatus which is specifically configured to store and execute a program command, such as a ROM, RAM or flash memory. The program command may include not only machine language codes created by a compiler, but also high-level language codes which can be executed by a computer using an interpreter.

Although some aspects of the present disclosure have been described in the context of the apparatus, the aspects may indicate the corresponding descriptions according to the method, and the blocks or apparatus may correspond to the steps of the method or the features of the steps. Similarly, the aspects described in the context of the method may be expressed as the features of the corresponding blocks or items or the corresponding apparatus. Some or all of the steps of the method may be executed by (or using) a hardware apparatus such as a microprocessor, a programmable computer or an electronic circuit. In some embodiments, one or more of the most important steps of the method may be executed by such an apparatus.

In some exemplary embodiments, a programmable logic device such as a field-programmable gate array may be used to perform some or all of functions of the methods described herein. In some exemplary embodiments, the field-programmable gate array may be operated with a microprocessor to perform one of the methods described herein. In general, the methods are preferably performed by a certain hardware device.

The description of the disclosure is merely exemplary in nature and, thus, variations that do not depart from the substance of the disclosure are intended to be within the scope of the disclosure. Such variations are not to be regarded as a departure from the spirit and scope of the disclosure. Thus, it will be understood by those of ordinary skill in the art that various changes in form and details may be made without departing from the spirit and scope as defined by the following claims.

What is claimed is:

1. A semiconductor device fabrication method comprising:
alternately and sequentially stacking a source/drain electrode layer forming a source/drain and a channel layer forming an oxide semiconductor channel;
stacking a mask layer to surround a portion where a source/drain region is to be formed;
exposing a channel layer of a channel region by etching and removing the source/drain electrode layer of the channel region exposed through the mask layer; and
sequentially forming a gate dielectric layer and at least one gate electrode layer on the exposed channel layer of the channel region and on exposed lateral sides of the source/drain electrode layer of the source/drain region.

2. The semiconductor device fabrication method of claim 1, wherein the sequentially forming the gate dielectric layer and the at least one gate electrode layer comprises forming the gate dielectric layer and the at least one gate electrode layer so that the gate dielectric layer is arranged for insulation between the channel layers and the gate dielectric layer is arranged for insulation between the channel layer and the at least one gate electrode layer, and the gate dielectric layer is arranged for insulation between the at least one gate electrode layer and the exposed lateral sides of the source/drain electrode layer of the source/drain region.

3. The semiconductor device fabrication method of claim 1, wherein the sequentially forming the gate dielectric layer and the at least one gate electrode layer comprises depositing the gate dielectric layer to surround the exposed channel layer in the channel region and the exposed lateral sides of the source/drain electrode layer of the source/drain region while maintaining the mask layer surrounding the portion where the source/drain region is to be formed.

4. The semiconductor device fabrication method of claim 3, wherein the sequentially forming the gate dielectric layer and the at least one gate electrode layer comprises depositing a first gate dielectric layer to surround the exposed gate dielectric layer in the channel region while maintaining the mask layer surrounding the portion where the source/drain region is to be formed.

5. The semiconductor device fabrication method of claim 4, wherein the sequentially forming the gate dielectric layer and the at least one gate electrode layer comprises depositing a second gate electrode layer to surround the first gate electrode layer in the channel region.

6. The semiconductor device fabrication method of claim 1, further comprising:
performing a dry etching process for the at least one gate electrode layer until the mask layer is exposed; and
removing the mask layer.

7. The semiconductor device fabrication method of claim 1, wherein
the channel layer comprises an N-type channel layer, and
the channel layer is formed of an oxide semiconductor compound that contains two or more elements from a group consisting of In, Ga, Zn, Sn, and O and has a band gap energy of 1.5 eV or more.

8. The semiconductor device fabrication method of claim 7, wherein the channel layer is formed of an oxide semiconductor compound that contains at least one element among Al, W, Hf, or Ta as impurities.

9. The semiconductor device fabrication method of claim 1, wherein
the channel layer comprises a P-type channel layer, and
the channel layer is formed of an oxide semiconductor compound that contains one or more elements from a group consisting of Zn, Te, Se, N, and O and has a band gap energy of 1.5 eV or more.

10. The semiconductor device fabrication method of claim 1, wherein the gate dielectric layer comprises a dielectric film that contains at least one of Al₂O₃, SiO₂, HfOₓ, or ZrOₓ.

11. A semiconductor device comprising:
a plurality of oxide semiconductor channel layers formed to extend in a first direction in a source/drain region and a channel region and formed in plural in a second direction intersecting the first direction;
a plurality of source/drain electrode layers formed between the plurality of oxide semiconductor channel layers in the second direction in the source/drain region;
a gate dielectric layer disposed between the plurality of source/drain electrode layers in the first direction in the channel region and disposed between the plurality of oxide semiconductor channel layers of the channel region in the second direction; and
at least one gate electrode layer formed to be connected between the gate dielectric layers in the channel region and formed to be connected to gate power, wherein
the plurality of oxide semiconductor channel layers and the plurality of source/drain electrode layers are alternately stacked in the second direction in the source/drain region.

12. The semiconductor device of claim 11, wherein the gate dielectric layer is formed for insulation between the plurality of oxide semiconductor channel layers, and formed for insulation between the plurality of oxide semiconductor channel layers and the at least one gate electrode layer.

13. The semiconductor device of claim 11, wherein
the plurality of oxide semiconductor channel layers comprise an N-type channel layer, and
the plurality of oxide semiconductor channel layers are formed of an oxide semiconductor compound that contains two or more elements from a group consisting of In, Ga, Zn, Sn, and O and has a band gap energy of 1.5 eV or more.

14. The semiconductor device of claim 13, wherein the plurality of oxide semiconductor channel layers are formed of an oxide semiconductor compound that contains at least one element among Al, W, Hf, or Ta as impurities.

15. The semiconductor device of claim 11, wherein
the plurality of oxide semiconductor channel layers comprise a P-type channel layer, and
the plurality of oxide semiconductor channel layers are formed of an oxide semiconductor compound that contains one or more elements from a group consisting of Zn, Te, Se, N, and O and has a band gap energy of 1.5 eV or more.

16. The semiconductor device of claim 11, wherein the gate dielectric layer comprises a dielectric film that contains at least one of Al₂O₃, SiO₂, HfOₓ, or ZrOₓ.

17. The semiconductor device of claim 11, further comprising:
a first semiconductor device of a first polarity type formed comprising the plurality of oxide semiconductor channel layers, the plurality of source/drain electrode layers, the gate dielectric layer, and the at least one gate electrode layer; and
a second semiconductor device of a second polarity type formed comprising a plurality of second oxide semiconductor channel layers, a plurality of second source/drain electrode layers, a second gate dielectric layer, and at least one second gate electrode layer, wherein
the first polarity type and the second polarity type are complementary to each other,
the first semiconductor device and the second semiconductor device are sequentially stacked in the second direction, and
the first semiconductor device and the second semiconductor device perform complementary logic operations.

18. A semiconductor device comprising:
a plurality of oxide semiconductor channel layers formed to extend in a first direction in a source/drain region and a channel region and formed in plural in a second direction intersecting the first direction; and
a plurality of source/drain electrode layers formed between the plurality of oxide semiconductor channel layers in the second direction in the source/drain region, wherein
the plurality of oxide semiconductor channel layers and the plurality of source/drain electrode layers are alternately stacked in the second direction in the source/drain region, and
a space is formed between the plurality of oxide semiconductor channel layers in the second direction in the channel region to expose the plurality of oxide semiconductor channel layers.

19. The semiconductor device of claim 18, wherein
the plurality of oxide semiconductor channel layers comprise an N-type channel layer, and
the plurality of oxide semiconductor channel layers are formed of an oxide semiconductor compound that contains two or more elements from a group consisting of In, Ga, Zn, Sn, and O and has a band gap energy of 1.5 eV or more.

20. The semiconductor device of claim 18, wherein
the plurality of oxide semiconductor channel layers comprise a P-type channel layer, and
the plurality of oxide semiconductor channel layers are formed of an oxide semiconductor compound that contains one or more elements from a group consisting of Zn, Te, Se, N, and O and has a band gap energy of 1.5 eV or more.
